(19) United States
(12) Patent Application Publication
(10) Pub. No.: US 2025/0316526 A1
(43) Pub. Date: Oct. 9, 2025

(54) MEASUREMENT REGIONS AND SUBSTRATE SUPPORT ASSEMBLIES FOR PROPERTY MEASUREMENTS

(71) Applicant: Applied Materials, Inc., Santa Clara, CA (US)

(72) Inventors: Zhepeng CONG, San Jose, CA (US); Nimrod SMITH, Cupertino, CA (US); Tao SHENG, Santa Clara, CA (US); Khokan C. PAUL, Cupertino, CA (US)

(21) Appl. No.: 18/625,924

(22) Filed: Apr. 3, 2024

(51) Int. Cl. H01L 21/67; H01L 21/687

(52) U.S. Cl. CPC H01L 21/68785; H01L 21/67115; H01L 21/67248; H01L 21/67253; H01L 21/68757; C30B 25/12

(57) ABSTRACT

Embodiments of the present disclosure relate to measurement substrates and substrate support assemblies for property measurements. In one or more embodiments, a substrate support assembly includes a substrate support, and a first insert sized and shaped for positioning in a first opening of the substrate support. The first insert includes a first measurement region.

### BACKGROUND

Embodiments of the present disclosure relate to calibration substrates and substrate support assemblies for property measurements, and related measuring systems, processing chambers, apparatus, and methods.

### DESCRIPTION OF THE RELATED ART

Semiconductor substrates are processed for a wide variety of applications, including the fabrication of integrated devices and microdevices. Properties (such as film growth rates and/or substrate temperatures) can be measured throughout deposition processes and after deposition processes. Over time, the sensor readings can drift due to changes of the conditions of the hardware within the process chamber. For example, aging of the heating lamps and/or substrate supports (among other factors) can affect the property measurements over time, hindering accuracy. Other factors can affect sensor measurements. For example, coating of window(s) can affect property measurements, hindering accuracy. Moreover, energy received that is not due to emissivity can affect accuracy of measurements. Measurement methods can involve opening of the process chamber and machine down time. Moreover, it can be difficult and time-consuming to measure multiple sensors at different locations.

Therefore, a need exists for improved methods and apparatus for measurements in systems that include thermal process chambers.

### SUMMARY

Embodiments of the present disclosure relate to measurement regions and substrate support assemblies for property measurements, and related measuring systems, processing chambers, apparatus, and methods.

In one or more embodiments, a substrate support assembly applicable for semiconductor manufacturing includes a substrate support including a plurality of openings, and a first insert sized and shaped for positioning in a first opening of the substrate support. The first insert includes a first measurement region.

In one or more embodiments, a processing chamber includes a chamber body at least partially defining a processing volume, and a substrate support disposed in the processing volume. The processing chamber includes one or more measurement regions at least partially supported by the substrate support. The one or more measurement regions respectively including a crystalline silicon carbide (SiC). The processing chamber includes one or more heat sources operable to heat the processing volume.

In one or more embodiments, a method of operation of a process chamber includes measuring one or more parameters of one or more inserts positioned at least partially in a substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a processing system, according to one or more embodiments.

FIG. 2 is a schematic enlarged view of the processing system shown in FIG. 1, according to one or more embodiments.

FIG. 3 is a schematic top view of the substrate support shown in FIG. 2 supporting one or more measurement regions, according to one or more embodiments.

FIG. 4 is a schematic sectional view of the measurement assembly used with respect to the process chamber of FIG. 1, according to one or more embodiments.

FIG. 5 is a partial schematic cross-sectional view of an in-situ reflectometer (ISR) that can be used as the growth rate sensor shown in FIGS. 1 and 2, according to one or more embodiments.

FIG. 6 is a schematic flow diagram view of a method of using the processing system of FIG. 1, according to one or more embodiments.

FIG. 7 is a schematic diagram view of a method of determining measurements applicable for semiconductor manufacturing, according to one or more embodiments.

FIG. 8 shows the measurement of the intensity of wavelengths over a range of wavelengths, according to one or more embodiments.

FIG. 9 shows a correlated temperature graph, according to one or more embodiments.

FIG. 10 is a schematic cross-sectional view a measurement assembly and the substrate support shown in FIGS. 2 and 3, according to one or more embodiments.

FIG. 11 is a schematic cross-sectional view a measurement assembly and the substrate support shown in FIGS. 2 and 3, according to one or more embodiments.

FIG. 12 is a schematic cross-sectional view of a substrate support and a measurement region, according to one or more embodiments.

FIG. 13 is a schematic top view of the substrate support and the measurement region shown in FIG. 12, according to one or more embodiments.

FIG. 14 is a schematic top view of the substrate support and the measurement region shown in FIG. 12, according to one or more embodiments.

FIG. 15 is a schematic cross-sectional view of a substrate support and a measurement region, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to measurement regions and substrate support assemblies for property measurements, and related measuring systems, processing chambers, apparatus, and methods.

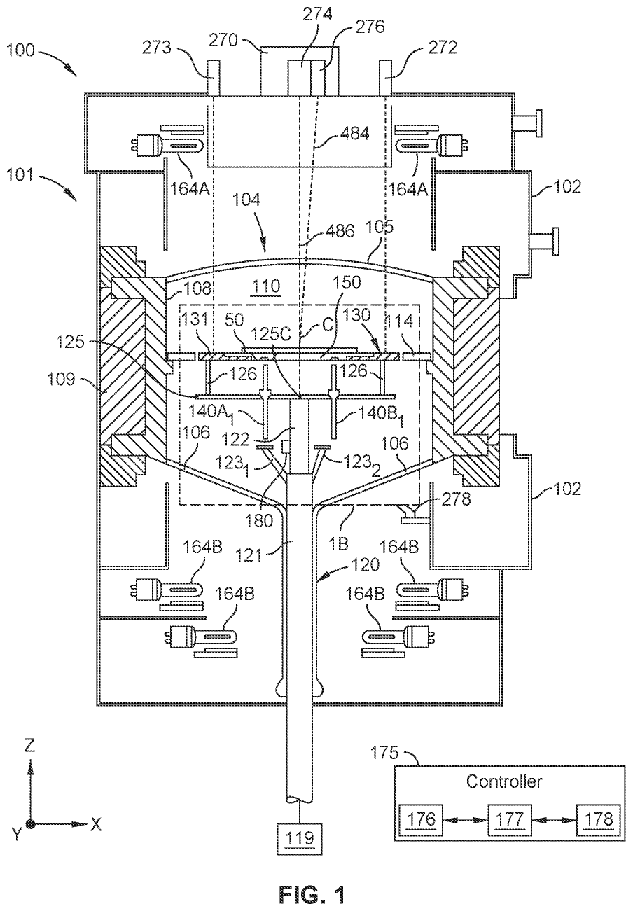

FIG. 1 is a schematic cross-sectional view of a processing system 100, according to one or more embodiments. The processing system 100 includes a process chamber 101 and a controller 175. The processing system 100 can be configured to conduct epitaxial deposition processes in the process chamber 101.

The process chamber 101 includes a housing structure 102 made of a process resistant material, such as aluminum or stainless steel, for example 316L stainless steel. The housing structure 102 can be at least part of a chamber body. The housing structure 102 encloses various functioning elements of the process chamber 101, such as a quartz chamber 104, which includes an upper quartz window 105 and a lower quartz window 106. The quartz chamber 104 encloses an interior volume 110 (also referred to as process volume). One or more liners 108, 109 can protect the housing structure 102 from reactive chemistry and/or can insulate the quartz chamber 104 from the housing structure 102.

The process chamber 101 includes a substrate support assembly 120. The substrate support assembly 120 includes a substrate support 130. In one or more embodiments, the substrate support 130 includes a susceptor assembly. A substrate 50 can be positioned on the substrate support 130 during processing, such as during depositions.

The process chamber 101 can further include upper heat sources 164A and lower heat sources 164B for heating of the substrate 50 and/or the interior volume 110. The heat sources 164A, 164B can be radiant heat sources such as lamps, for example halogen lamps and/or infrared (IR) lamps. In one or more embodiments, the heat sources 164A, 14B are operable to emit IR light and/or ultraviolet light. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support assembly 120 can include an actuator 119, an outer shaft 121, and inner shaft 122. The actuator 119 is configured to vertically move the inner shaft 122 relative to the outer shaft 121. The actuator 119 is further configured to rotate the inner shaft 122 while the outer shaft 121 remains stationary. The inner shaft 122 is configured to rotate about a central axis C extending in the vertical direction through the center of the inner shaft 122.

The substrate support assembly 120 includes the substrate support 130, a support plate 125, and a plurality of support pins 126, such as three support pins 126 positioned 120 degrees apart from each other a same distance from the central vertical axis C. In one or more embodiments, the support plate 125 and the support pins 126 can be formed of quartz or silicon carbide. The support plate 125 is positioned over (e.g., directly on) the inner shaft 122. The support plate 125 can include a center 125C aligned with the central vertical axis C. The support pins 126 are each positioned over (e.g., directly on) the support plate 125. The substrate support 130 is positioned over (e.g., directly on) the support pins 126.

The substrate support 130 includes an outer section 131 and an inner section 150. The inner section 150 is positioned on and supported by the outer section 131. The inner section 150 can be easily moved (e.g., lifted) from the outer section 131 as described in fuller detail below. In one or more embodiments, the inner section 150 and/or the outer section 131 are formed of an opaque material (such as white quartz, grey quartz, quartz with impregnated particles (such as SiC particles or silicon particles), black quartz, silicon carbide (SiC), and/or graphite coated with SiC). In one or more embodiments, the outer section 131 can have a ring shape. The outer section 131 can be positioned around the inner section 150. The inner section 150 can be positioned on a portion of the outer section 131 as described in further detail below. The process chamber 101 can include a preheat ring 114 that can be positioned around the substrate support 130.

The substrate support assembly 120 includes a first plurality of lift pins 140A and a second plurality of lift pins 140B. One of each plurality of lift pins 140A, 140B is shown in FIG. 1 to simplify the drawing. In one or more embodiments, the first plurality of lift pins 140A and the second plurality of lift pins 140B can be formed of quartz (such as transparent quartz). In one or more embodiments, the first plurality of lift pins 140A includes three lift pins 140A₁₋₃, and the second plurality of lift pins 140B includes three lift pins 140B₁₋₃. The first and second pluralities of lift pins 140A, 140B can include two lift pins of each type or more than three lift pins of each type.

The first plurality of lift pins 140A can be positioned and configured to lift a substrate 50 above the substrate support 130 to allow the substrate 50 to be transferred to and from the interior volume 110 of the process chamber 101. The second plurality of lift pins 140B can be positioned and configured to lift the inner section 150 of the substrate support 130 above the outer section 131 of the substrate support 130 to allow the inner section 150 of the substrate support 130 to be transferred to and from the interior volume 110 of the process chamber 101.

The substrate support assembly 120 can further include three lift pin pads 123. More or less lift pin pads (e.g., two lift pin pads) can be used. Each lift pin pad 123 can be attached to the outer shaft 121. In one or more embodiments, the lift pin pads 123 can be formed of quartz (such as transparent quartz).

The lift pin pads 123 can be positioned 120 degrees apart from each other relative to the central axis C that extends through a center of the outer shaft 121. A first lift pin pad 123₁ and a second lift pin pad 123₂ are shown in FIG. 1. A third lift pin pad 123₃ is not visible in FIG. 1. Each of the lift pin pads 123 is also positioned at a same distance from the central axis C as the distance of each of the lift pins 140A, 140B from the center 125C of the support plate 125. As described in further detail below, the position of the lift pads 123 allows the substrate support assembly 120 to rotate the support plate 125 (1) to a substrate-lifting position (first position) in which each of the first plurality of lift pins 140A₁₋₃ overlies one of the lift pin pads 123 or (2) to an inner section-lifting position (second position) in which each of the second plurality of lift pins 140B₁₋₃ overlies one of the lift pin pads 123. Used herein, “overlies” and “underlies” refer to components that have different vertical positions, but at least partially overlap in horizontal positions along respective XY planes thereof.

When the support plate 125 is in the substrate-lifting position, the actuator 119 can lower the inner shaft 122 causing the lift pins 140A to contact the lift pin pads 123 and push the substrate 50 above the inner section 150 of the substrate support 130 using movable lift pin caps as described in further detail below. When the actuator 119 lowers the inner shaft 122 to cause the first plurality of lift pins 140A to contact the lift pin pads 123 with the support plate 125 in the substrate-lifting position, the second plurality of lift pins 140B do not contact any lift pin pads 123 and instead move closer to the lower quartz window 106.

When the support plate 125 is in the inner section-lifting position, the actuator 119 can lower the inner shaft 122 causing the lift pins 140B to contact the lift pin pads 123 and push the inner section 150 of the substrate support 130 above the outer section 131 as described in further detail below. When the actuator 119 lowers the inner shaft 122 to cause the second plurality of lift pins 140B to contact the lift pin pads 123 with the support plate 125 in the inner section-lifting position, the first plurality of lift pins 140A do not contact any lift pin pads 123 and instead move closer to the lower quartz window 106.

In one or more embodiments, one or more of the lift pin pads 123 can include a sensor (e.g., a proximity sensor) connected to the controller 175 to detect when one of the lift pins 140A, 140B overlies lift pin pad 123. The controller 175 can use the feedback from the sensor to stop the rotation of the support plate 125 by the actuator 119. This can enable the controller to align the first plurality of lift pins 140A to overlie the lift pin pads 123 for lifting the substrate 50 or to align the first plurality of lift pins 140B to overlie the lift pin pads 123 to lift the inner section 150.

In one or more embodiments, the process chamber 101 can include an encoder 180. In one or more embodiments, the encoder can be attached to an outside of the inner shaft 122, such as near a bottom of the inner shaft 122. The encoder 180 can be used to control the angular amount (e.g., 60 degrees, 90 degrees, 180 degrees, etc.) from a home position that the substrate support 130 has rotated. Determining and controlling this angular rotation of the inner shaft 122 enables the substrate support 130 to be rotated to any angle from a home position, which provides the capability for the substrate support 130 and substrate 50 to be rotated to angular positions, such as a first position aligning the lift pin pads 123 with the first plurality of lift pins 140A and a second position aligning the lift pin pads 123 with the second plurality of lift pins 140B.

The processing system 100 also includes the controller 175 for controlling processes performed by the processing system 100. The controller 175 can be any type of controller used in an industrial setting, such as a programmable logic controller (PLC). The controller 175 includes a processor 177, a memory 176, and input/output (I/O) circuits 178. The controller 175 can include one or more of the following components, such as one or more power supplies, clocks, communication components (e.g., network interface card), and user interfaces typically found in controllers for semiconductor equipment.

The memory 176 can include a non-transitory memory (e.g., a non-transitory computer readable medium). The non-transitory memory can be used to store the programs and settings described below. The memory 176 can include one or more readily available types of memory, such as read only memory (ROM) (e.g., electrically erasable programmable read-only memory (EEPROM)), flash memory (e.g., flash drive), floppy disk, hard disk, random access memory (RAM) (e.g., non-volatile random access memory (NVRAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), or any other form of digital storage, local or remote.

The processor 177 is configured to execute various programs stored in the memory 176, such as epitaxial deposition processes and processes for transferring substrates and substrate supports into and out of the interior volume 110. During execution of these programs, the controller 175 can communicate to I/O devices through the I/O circuits 178. For example, during execution of these programs and communication through the I/O circuits 178, the controller 175 can control outputs, such as the rotational position of substrate support 130 relative to the lift pin pads 123 and the vertical position of the substrate support 130 through use of the actuator 119. The memory 176 can further include various operational settings used to control the processing system 100.

The controller 175 is configured to conduct any of the operations described herein. In one or more embodiments, the instructions stored on the memory 176, when executed, cause one or more of operations of method 600 and/or the method 700 (described below) to be conducted in relation to the processing chamber 101. The various operations described herein (such as the operations of the method 600 and/or the method 700) can be conducted automatically using the controller 175, or can be conducted automatically or manually with certain operations conducted by a user.

The controller 175 can include one or more machine learning and/or artificial intelligence (ML/AI) algorithms. The one or more ML/AI algorithms can optimize the measurements of the temperature (of operation 704), the growth rate (of operation 706) and the reference temperature (of operation 708). The one or more ML/AI algorithms can use, for example, a regression model (such as a linear regression model) or a clustering technique to estimate optimized parameters. The algorithm can be unsupervised or supervised. In one or more embodiments, the controller 175 automatically conducts the operations described herein without the use of one or more ML/AI algorithms. In one or more embodiments, the controller 175 compares measurements to data in a look-up table and/or a library to determine if the fault condition is detected. The controller 175 can store measurements as data in the look-up table and/or the library.

The processing system 100 includes a measurement assembly 270, according to one or more embodiments. The controller 175 can control the measurement assembly 270, and conduct calibration of one or more sensors 272, 273, 276, 278 (four are shown). In one or more embodiments, the one or more sensors 272, 273, 276, 278 include a first temperature sensor 272, a growth rate sensor 273, a band edge sensor 276, and a second temperature sensor 278. In one or more embodiments, the sensors 272, 273, 276, 278 respectively include a sensor that includes one or more of silicon (Si), carbon (C), gallium (Ga), and/or nitrogen (N). In one or more embodiments, the sensors 272, 273, 276, 278 respectively include a silicon sensor, a silicon carbide (SiC) sensor, and/or a gallium nitride (GaN) sensor. In one or more embodiments, the temperature sensors 272, 278 respectively include a pyrometer. The measurement assembly 270 facilitates accurate measurement of the temperature of the substrate 50 and/or a film growth rate on the substrate 50. The measurement assembly 270 includes an energy source 274 (e.g., a light source) and a band edge detector 276. The first (e.g., upper) temperature sensor 272, the growth rate sensor 273, the energy source 274, and the band edge detector 276 are disposed above the substrate 50. A lower temperature sensor 278 is disposed below the substrate 50. The energy source 274 and the band edge detector 276 are part of a sensor assembly of the measurement assembly 270.

In one or more embodiments, the growth rate sensor 273 is used to measure a growth rate on a measurement region including SiC having a 3C atomic structure, the band edge detector 276 is used to measure a reference temperature on a measurement region including SiC having a 4H or 6H atomic structure, and the temperature sensor 272 is used to measure a temperature on a measurement region including SiC having a 4H or 6H atomic structure.

The energy source 274 is positioned to emit a first energy, and the band edge detector 276 is disposed adjacent to the energy source 274 and positioned to receive the first energy.

The energy source 274 is a laser light source with a controlled intensity and wavelength range. In one or more embodiments, a broad band light source is used. The energy source 274 may be a diode laser or an optical cable. When the energy source 274 is an optical cable, the optical cable is connected to an independent energy source (e.g., light source), which may be disposed near the process chamber 101. The energy source 274 may be a bundle of lasers or optical cables, such that a plurality of beams (e.g., light beams) are focused into a first beam 486 (e.g., light beam). In one or more embodiments, the energy source 274 can emit radiation at a varying wavelength range. The varying wavelength range allows the energy source 274 to emit wavelengths which would be within about 200 nm of the expected absorption edge wavelength of a measurement region (described below). The use of a varying wavelength range eliminates noise which may be caused by the use of a wider wavelength spectrum and allows for an increase in the strength of emission of the narrower range from the energy source 274 to increase the signal strength received by the band edge detector 276. In one or more embodiments, one or more of the heat sources 164A are used as the energy source 274. In one or more embodiments, the energy source 274 may be classified as a radiation source, such as a thermal radiation source or a broad band radiation source. The radiation source may be a laser diode or an optical assembly. The optical assembly may include a laser, a lamp, and/or a bulb; and/or a plurality of lenses, mirrors, or a combination of lenses and mirrors.

The band edge detector 276 measures the intensity of different wavelengths of energy (e.g., light) within a second beam 284 (e.g., light beam), which is reflected off the measurement region 350. The band edge detector 276 is configured to find a wavelength at which the measurement region 350 transitions from absorbing a wavelength of radiation to reflecting nearly all of a wavelength of radiation. The band edge detector 276 may include several optical components disposed therein in order to separate and measure the second beam 284. In one or more embodiments, the band edge detector 276 is a scanning band edge detector and scans through a range of wavelengths to determine the transition wavelength at which the measurement region (which is in place of the substrate 50) transitions from absorbing to reflecting radiation. In one or more embodiments, the band edge detector 276 measures the intensity of wavelengths of energy (e.g., light) transmitted through a first measurement region (described below) from below the first measurement region (such as through a hole 279 and then through the first measurement region 260 described below). The intensity of wavelengths of the radiation transmitted through the first measurement region may be measured by the band edge detector 276. The band edge detector 276 then determines a transition wavelength at which the first measurement region 260 transitions from absorbing wavelengths to transmitting wavelengths. An optional filter may be placed between the band edge detector 276 and the inner and outer sections 131, 250 (described below) and configured to filter out radiation emitted by the heat sources 164A, 164B. The measurement regions described herein can respectively correspond to sensor sites.

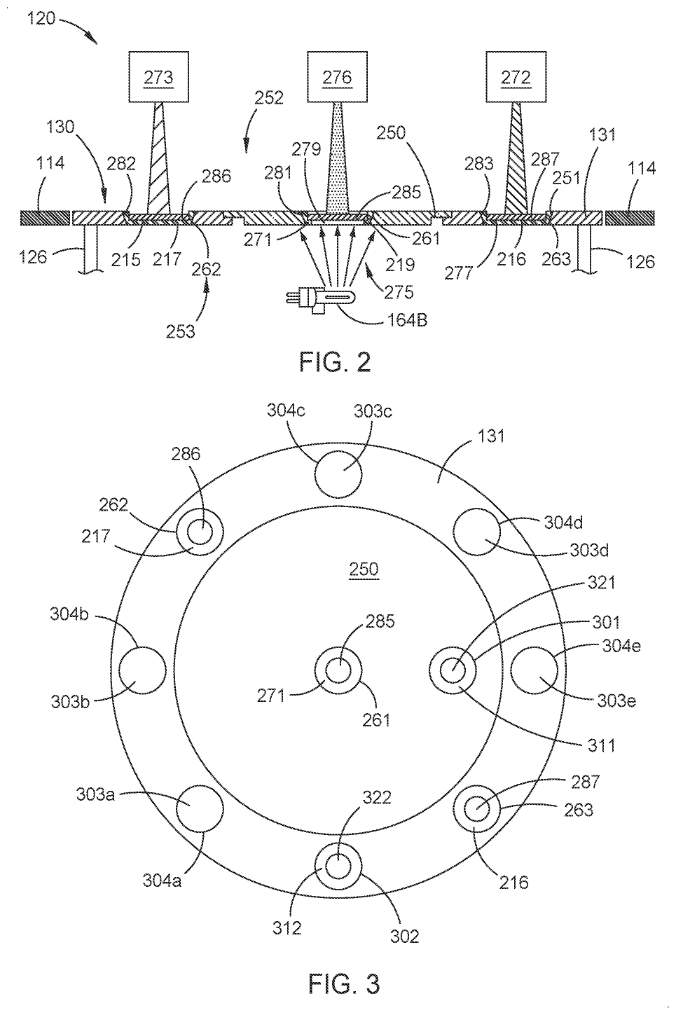

FIG. 2 is a schematic enlarged view of the processing system 100 shown in FIG. 1, according to one or more embodiments. In the implementation shown in FIG. 2, the inner section 150 has been replaced with an inner section 250.

The substrate support 130 includes a plurality of openings 261-263 (three are shown in FIG. 2). The substrate support assembly 120 includes a first insert 271 sized and shaped for positioning in a first opening 261 of the substrate support 130, a second insert 217 sized and shaped for positioning in a second opening 262 of the substrate support 130, and a third insert 216 sized and shaped for positioning in a third opening 263 of the substrate support 130. The first insert 271 includes a first retention opening 275, and a first measurement region 285 is sized and shaped for positioning in the first retention opening 275. The second insert 217 includes a second retention opening 215, and a second measurement region 286 is sized and shaped for positioning in the second retention opening 215. The third insert 216 includes a third retention opening 277, and a third measurement region 287 is sized and shaped for positioning in the third retention opening 277. The first retention opening 275 includes a first recess 219 at least partially defining a first support surface, and a hole 279 extending into the first support surface defined at least partially by the first recess 219. The second retention opening 215 includes a second recess at least partially defining a second support surface. The third retention opening 277 includes a third recess at least partially defining a third support surface.

As shown in FIG. 2, the measurement regions 285, 286, 287 can respectively include a measurement substrate respectively supported by the inserts 216, 217, 271. The present disclosure contemplates that the measurement substrates can be omitted, and the measurement regions 285, 286, 287 can be at least part of the inserts 216, 217, 271. The present disclosure contemplates that the measurement regions 285, 286, 287 can be integrally formed with the inserts 216, 217, 271. For example, the measurement regions 285, 286, 287 can respectively include a layer (such as an upper layer) respectively of the inserts 216, 217, 271.

The first insert 271 includes one or more outer surfaces 281 sized and shaped to abut against one or more inner surfaces defined at least partially by the first opening 261 of the substrate support 130. In one or more embodiments, the one or more outer surfaces 281 have a taper angle that is substantially equal to a taper angle of the one or more inner surfaces defined at least partially by the first opening 261. The second insert 217 includes one or more outer surfaces 282 sized and shaped to abut against one or more inner surfaces defined at least partially by the second opening 262 of the substrate support 130. In one or more embodiments, the one or more outer surfaces 282 have a taper angle that is substantially equal to a taper angle of the one or more inner surfaces defined at least partially by the second opening 262. The third insert 216 includes one or more outer surfaces 283 sized and shaped to abut against one or more inner surfaces defined at least partially by the third opening 263 of the substrate support 130. In one or more embodiments, the one or more outer surfaces 283 have a taper angle that is substantially equal to a taper angle of the one or more inner surfaces defined at least partially by the third opening 263. Other shapes may be used for the outer surfaces 281-283 and the interfacing inner surfaces. For example, curved shapes having substantially equal radii of curvature may be used. As another example, stepped rectangular shapes having substantially equal widths and heights may be used.

In the implementation shown in FIG. 2, the substrate support 130 includes the inner section 250 and the outer section 131. The outer section 131 is sized and shaped to support an outer region of the inner section 250. The inner section 250 includes the first opening 261, and the outer section 131 includes the second opening 262 and the third opening 263. The inner section 250 includes an outer shoulder 251, a first face 252, and a second face 253 opposing the first face 252. The inner section 250 is movable relative to the outer section 131. The present disclosure contemplates that the inner section 250 can be coupled to (e.g., integrally formed with or fused to) the outer section 131.

The first measurement region 285, the second measurement region 286, and the third measurement region 287 respectively include a crystalline silicon carbide (SiC), such as a monocrystalline SiC. The respective measurement regions can be formed of the crystalline SiC and/or can include graphite coated with the crystalline SiC. In one or more embodiments, the first measurement region 285 and the third measurement region 287 respectively include (SiC) having an atomic structure that is 4H or 6H. In one or more embodiments, the second measurement region 286 includes SiC having an atomic structure that is 3C. In one or more embodiments, the first measurement region 285 is formed of crystalline SiC having the 4H atomic structure. The inserts 271, 217, 216 and/or the substrate support 130 (such as the inner section 250 and/or the outer section 131) respectively are formed of the crystalline SiC or include graphite coated with the crystalline SiC. In one or more embodiments, the crystalline SiC of the inserts 271, 217, 216 have the atomic structure that is 3C. The crystalline SiC can facilitate resistance to etching and enhanced operational lifespans. In one or more embodiments, the first measurement region 285 and the third measurement region 287 respectively include a first material having a bandgap that is at least 2.5 eV, such as at least 3.0 eV. In one or more embodiments, the first material has a lattice constant that is at least 2.5, such as at least 3.0. In one or more embodiments, the second measurement region 286 includes a second material having a bandgap that is at least 1.5 eV, such as at least 2.0 eV. In one or more embodiments, the second material has a lattice constant that is at least 3.5, such as at least 4.0. The bandgap of the first material and/or the second material can be at least 3.5 eV, such as at least 4.0 eV.

The inner section 250 and/or the outer section 131 includes a third material. In one or more embodiments, the third material includes SiC having an atomic structure that is 3C. In one or more embodiments, the third material includes SiC that is amorphous or polycrystalline. In one or more embodiments, the third material has a bandgap that is at least 1.5 eV, such as at least 2.0 eV. In one or more embodiments, the third material has a lattice constant that is at least 3.5, such as at least 4.0. The bandgap of the third material can be at least 3.5 eV, such as at least 4.0 eV. In one or more embodiments, the SiC of the third material is different than the SiC of the first material and/or the SiC of the second material.

FIG. 3 is a schematic top view of the substrate support 130 shown in FIG. 2 supporting one or more measurement regions 261-266, according to one or more embodiments.

In the implementation shown in FIG. 3, the inner section 250 includes an additional measurement region 321 disposed in an additional insert 311 in an additional opening 301. The outer section 131 includes an additional measurement region 322 disposed in an additional insert 312 in an additional opening 302. One of the additional opening 301 and the additional opening 302 can be referred to as a third opening, and another of the additional opening 301 and the additional opening 302 can be referred to as a fourth opening. Plug inserts 303a-303e are disposed in a plurality of openings 304a-304e. The plug inserts 303a-303e omit retention openings and reduce or prevent gas flow through the openings 304a-304e. The present disclosure contemplates that one or more of the plug inserts 303a-303e can be replaced with an insert including a retention opening and/or one or more of the inserts 271-273, 311, 312 can be replaced with a plug insert. The plug inserts 303a-303e and/or the inserts 271-273, 311, 312 can be transferred into and out of the process chamber 101. When not in the process chamber 101, the plug inserts 303a-303e and/or the inserts 271-273, 311, 312 can be stored at a location (such as on a cassette) exterior to the process chamber 101, such as in a transfer chamber and/or in a load lock chamber.

The third insert 216, the second insert 217, the additional insert 312, and the plug inserts 303a-303e (and associated openings) are disposed radially outwardly of the first insert 271 and the associated first opening 261. The additional insert 311 is disposed radially between the first insert 271 and the outward inserts and plug inserts 217, 216, 312, 303a-303e.

The present disclosure contemplates that a different number of measurement regions, inserts, and/or openings can be used than shown in FIG. 3.

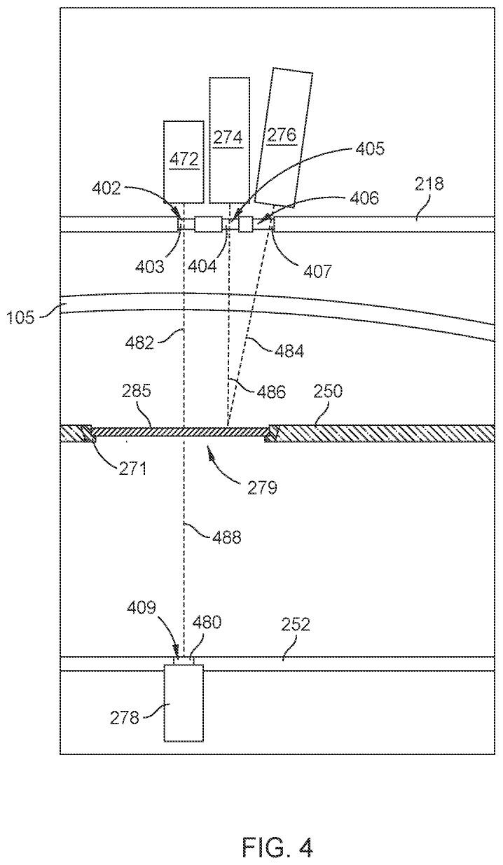

FIG. 4 is a schematic sectional view of the measurement assembly 270 used with respect to the process chamber 101 of FIG. 1, according to one or more embodiments. In addition to the components described with regard to FIG. 1, the measurement assembly 270 of FIG. 4 includes a first window 403, a second window 408, a third window 404, a fourth window 407, and a cover 420.

The first window 403 is disposed within a first opening 402. The first window 403 is disposed between a second upper temperature sensor 472 and the upper window 105. The first window 403 is disposed between the second upper temperature sensor 472 and the one or more measurement regions 285-287, 321, 322. The first window 403 is a quartz window and allows for radiation from within the process chamber 101 to pass therethrough. The first window 403 may filter radiation emitted by the one or more measurement regions 285-287, 321, 322 to allow wavelengths which the second upper temperature sensor 472 measures while filtering other wavelengths. The radiation traveling along the first measurement radiation path 482 travels between a top side of the first measurement region 285 and the second upper temperature sensor 472. The first measurement radiation path 482 intersects both the upper window 105 and the first window 403. In one or more embodiments, the first measurement radiation path 482 may intersect the top side of the first measurement region 285 at any radial position along the first measurement region 285. In one or more embodiments, the first measurement radiation path 482 intersects the top side of the measurement region 285 at a specific location, such as either less than 15 mm from the center of the measurement region 285, such as less than 10 mm from the center of the measurement region 285, such as less than 5 mm from the center of the measurement region 285 or the first measurement radiation path 482 intersects the top side of the measurement region 285 at a radius of about 110 mm to about 130 mm, such as about 115 mm to about 125 mm, such as about 120 mm.

The second window 408 is disposed within a second opening 409. The second window 408 is disposed between the lower temperature sensor 278 and the lower window 106. Therefore, the second window 408 is disposed between the lower temperature sensor 278 and the first measurement region 285. In the implementation shown in FIG. 4, the lower temperature sensor 278 is aligned approximately below a center of the first measurement region 285. The second window 408 is a quartz window and allows for radiation from within the process chamber 101 to pass there through. The second window 408 may filter radiation emitted by the first measurement region 285 to allow wavelengths which the lower temperature sensor 278 measures while filtering other wavelengths. The radiation traveling along the second measurement radiation path 488 travels between the bottom side of the first measurement region 285 and the lower temperature sensor 278. The second measurement radiation path 488 intersects both the lower window 106 and the second window 408. In one or more embodiments, the second measurement radiation path 488 may intersect the bottom side of the first measurement region 285 or the inner section 250 at any radial position along the first measurement region 285. In one or more embodiments, the second measurement radiation path 488 intersects the bottom side of the first measurement region 285 at a specific radial position, such as a radial position directly below the first measurement region 285 and either less than 15 mm from the center of the first measurement region 285, such as less than 10 mm from the center of the first measurement region 285, such as less than 5 mm from the center of the first measurement region 285 or the second measurement radiation path 488 intersects the bottom side of the first measurement region 285 at a radial position directly below the first measurement region 285 at a radius of about 110 mm to about 130 mm, such as about 115 mm to about 125 mm, such as about 120 mm.

The third window 404 is disposed within a third opening 405. The third window 404 is disposed between the energy source 274 and the upper window 105. The third window 404 is disposed between the energy source 274 and the first measurement region 285. The third window 404 allows energy (e.g., light) emitted by the energy source 274 to pass there through. The energy emitted by the energy source 274 and traveling along the first beam 486 is disposed between the energy source 274 and the top side of the first measurement region 285. The first beam 486 passes through both of the upper window 105 and the third window 404. The first beam 486 may intersect the top side of the first measurement region 285 at any radial position along the first measurement region 285. In one or more embodiments, the first beam 486 intersects the top side of the first measurement region 285 either less than 15 mm from the center of the measurement region 285, such as less than 10 mm from the center of the measurement region 285, such as less than 5 mm from the center of the measurement region or the first beam 486 intersects the top side of the first measurement region 285 at a radius of about 110 mm to about 130 mm, such as about 115 mm to about 125 mm, such as about 120 mm.

The first beam 486 intersects the top side of the first measurement region 285 within less than 5 mm, such as less than 2 mm, such as less than 1 mm from the location in which the first measurement radiation path 482 intersects the radiation path. In one or more embodiments, the first beam 486 intersects the top side of the first measurement region 285 at the same radial position as the first measurement radiation path 482. Measuring the first measurement region 285 at the same location can allow for a direct comparison between temperature measurements and reduce error when compared to measurements made at different radial distances from the center of the first measurement region 285.

The fourth window 407 is disposed within a fourth opening 406 formed through a chamber lid 218. The fourth window 407 is disposed between the band edge detector 276 and the upper window 105. The fourth window 407 is disposed between the band edge detector 276 and the measurement region 260A.

The energy (e.g., light) received by the band edge detector 276 and traveling along the second beam 484 is disposed between the band edge detector 276 and the top side of the first measurement region 285. The second beam 484 passes through both of the upper window 105 and the fourth window 407. The second beam 484 intersects the top side of the first measurement region 285 at the same location as the first beam 486. The second beam 484 is a reflection of the first beam 486 off the top side of the first measurement region 285. The second beam 484 is altered by intersecting the first measurement region 285 and has a reduced wavelength range that is measured by the band edge detector 276.

The temperature of a portion of the first measurement region 285 and/or the inner section 250 can be measured using the second upper temperature sensor 472. The temperature of a portion of the first measurement region 285 and/or the inner section 250 can be measured using the lower temperature sensor 278 is a temperature of a bottom surface disposed opposite the location at which the temperature is measured by the second upper temperature sensor 472. The present disclosure contemplates that the second upper temperature sensor 472 can be omitted, and the band edge detector 276 can be used in conjunction with the upper temperature sensor 272 shown in FIG. 1.

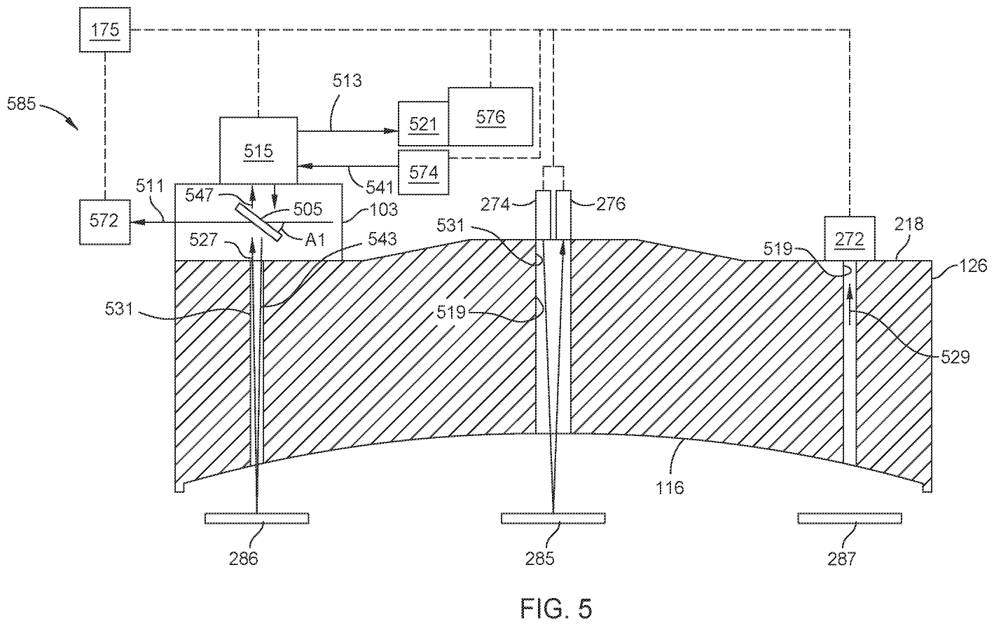

FIG. 5 is a partial schematic cross-sectional view of an in-situ reflectometer (ISR) 585 that can be used as the growth rate sensor 273 shown in FIGS. 1 and 2, according to one or more embodiments. The present disclosure contemplates that other growth sensors, such as other reflectometers, may be used for the growth rate sensor 273. The present disclosure contemplates that any type of spectrometer(s) (such as optical spectrometer(s), for example a multi-channel spectrometer or a spectrograph configured to measure wavelength-resolved intensity) operable to detect (e.g., scan) a band edge range for a temperature range may be used for the band edge detector 276. The ISR System 185 includes an energy source 574, a collimator 515, a detector 576, a temperature sensor 572, and a dichroic mirror 505 coupled to or disposed above the chamber lid 218. The ISR 585 facilitates measurement of one or more properties of the second measurement region 286 (and/or a film disposed thereon). Example properties include temperature, film growth rate, thickness of a film, film optical properties and/or in-film Ge concentration.

The energy source 574 is configured to generate energy 541 (e.g., radiation, such as light). For example, the energy source 574 could be a flash lamp, capable of producing full spectrum or partial spectrum light. In one or more embodiments, the spectrum of light generated has a wavelength between about 200 nm to about 4 micrometers, such as 200 nm to about 800 nm and/or 3 micrometers to 4 micrometers. Full spectrum light facilitates a wide range of light signals for analysis. In one or more embodiments, a light source may be limited to a specific wave length of light or specific range of light wave lengths to accomplish the analysis. The energy source 574 may be controlled by the controller 175. The energy source 574 is in optical communication with the collimator 515, and directs energy 541 to the collimator 515 upon instruction of the controller 175. Optical communication includes connection by a fiber optic cable, and other modes of light transmission are contemplated. The travel path of the energy from the energy source 574 may be referred to as a propagation path. The collimated energy 543 (e.g., radiation, such as light) leaves the collimator 515, and travels through a passage 531. In one or more embodiments, the passage 531 includes a light pipe. The passage 531 can be a made of any material capable of transmitting light of predetermined wavelengths, for example, sapphire. The passage 531 directs the collimated energy 543 to the surface of the second measurement region 286 (or a film thereon) or the surface of the second measurement region 286 to facilitate measurement of one or more properties (such as film growth rate) of the second measurement region 286 (or a film thereon).

The collimated energy 543 is reflected off the target measurement surface, such as on the second measurement region 286, and is reflected back as reflected energy 527. The reflected energy 527 travels back through the passage 531. The reflected energy 527 leaves the passage 531 and travels to the dichroic mirror 505 aligned with the passage 531 along the travel path of the reflected energy 527. In one or more embodiments, the dichroic mirror 505 includes a transparent material with a dielectric coating. The dielectric coating may include, but is not limited to, magnesium fluoride, tantalum pentoxide, and/or titanium dioxide. The dichroic mirror 505 reflects certain wavelengths of energy (e.g., light) away to the temperature sensor 572, but allows other selected wavelengths to pass through to the collimator 515. A wavelength range directed to the detector 576 through the collimator 515 may be between, for example, about 100 nm and about 1000 nm, such as within a range of 200 nm and 800 nm, such as within a range of 200 nm and 400 nm, and such as within a range of 400 nm and 800 nm. Other wavelengths are contemplated. The dichroic mirror 505 facilitates multiple light based sensors to be used by directing light of a first desired range of to one sensor (such as the detector 576) with the remaining light wavelengths being sent to at least another sensor (such as the temperature sensor 572). The dichroic mirror 505 is arranged, or oriented, at an angle of incidence A1 between about, 30° and about 60°, such as within a range of 35° and 55°, with a plane near orthogonal to a longitudinal axis of the passage 531. However, other angles of incidence are contemplated.

As shown in FIG. 5, light reflected from the dichroic mirror 505 is transmitted to the upper temperature sensor 572 along an energy path 511 (e.g., a light path). In one or more embodiments, light wavelengths between about 1.0 μm and about 6.0 μm, such as between about 3.0 μm and about 4.0 μm, travel along the energy path 511 to the temperature sensor 572. As noted above, properties of the dichroic mirror 505 are selected to transmit or reflect light in specified wavelength ranges. Energy 547 (e.g., light) allowed to pass through the dichroic mirror 505 is collimated by the collimator 515. The collimated energy 513 is directed to the detector 576 that is operable to measure a growth rate of film. In one or more embodiments, the detector 576 includes a photodiode detector. The detector 576 can include a grating, an optical lens, a filter 521 and/or a linear-array photodiode detector. The present disclosure contemplates that any type of spectrometer(s) (such as optical spectrometer(s), for example a multi-channel spectrometer or a spectrograph configured to measure wavelength-resolved intensity) operable to detect (e.g., scan) a film growth for a temperature range may be used for the detector 576. The filter 521 can be a short pass filter to limit the noise from a heat source (such as the heat sources 164A, 164B), or a dielectric filter. A dielectric filter includes any thin film based filters than can reduce or prevent specific wavelength of light from passing therethrough. While the filter 521 is described as part of the detector 576, it is contemplated that the filter can be located in other locations. For example, the filter 521 can be part of the dichroic mirror 505. The filter 521 is configured to allow light of a selected wavelength to pass therethrough, while reducing or preventing passing or other wavelengths. In one or more embodiments, the filter 521 allows light of wavelengths below 550 nm to pass therethrough (while filtering other wavelengths) to mitigate light signal noise from heat sources of the process chamber, thus improving measurement accuracy. It is contemplated that the filter 521 can be placed in any light path that includes the light reflected off the second measurement region 286 (e.g., reflected energy 527 to the detector 576, reflected energy 547 from dichroic mirror 505, and/or collimated energy 543). In one or more embodiments, the filter 521 is an integral component of the detector 576. In one or more embodiments, the filter 521 is a standalone component from the detector 576. In one or more embodiments, the filter 521 is not included in the path. It is to be noted that while one or more embodiments described herein may include a filter 521 and/or a dichroic mirror 505, both the filter 521 and the mirror 505 are optional and may be excluded from any embodiment or implementation described herein. The present disclosure contemplates that the temperature sensor 572 (e.g., a pyrometer) can be omitted from the ISR 585.

The energy source 274, the band edge detector 276, and the upper temperature sensor 272 respectively are configured to be in line (e.g., vertically and/or optically aligned) with passages 519. The passages 519 extend between a bottom surface and an upper surface of the chamber lid 218. The passages 519 may be sealed at upper and lower ends thereof by a material capable of transmitting energy 529 (e.g., light), such as quartz or sapphire. In one or more embodiments, each passage 519 includes a fiber optic cable disposed thereon.

In one or more embodiments, an energy source (similar to the energy source 574), a collimator (similar to the collimator 515), a housing (similar to a housing 103), a mirror (similar to the dichroic mirror 505), and/or a filter (similar to the filter 521) are used in relation to the band edge detector 276 and/or the upper temperature sensor 272.

For the ISR 585, the reflected signal travels back to the dichroic mirror and is split into multiple paths (e.g., propagation sub-paths). A first propagation sub-path directs reflected light to the respective temperature sensor 572 (if used), while a second propagation sub-path directs reflected light to the collimator 515 and then to the detector 576. The light intensity collected by the detector 576 can be analyzed for true reflectance, which is compared with models, for example (Fresnel equations) using nonlinear fitting equations or other empirically derived equations to determine a growth rate reading.

In one or more embodiments, models are empirically derived by obtaining absorption/reflectance data for light at predetermined wavelengths for various materials of various measurement regions. The data may be collected at conditions which approximate those of a predetermined recipe for processing future substrates, such as a process recipe at which the model will be used. The data is then fit to an equation, such as a non-linear equation. Light received by the detector 576 is analyzed for intensity (e.g., true reflectance of light reflected from the measured measurement region 286) and fit to the empirically derived equation to determine the adjusted growth rate reading. Stated otherwise, the amount of light reflected from the measurement region surface changes depending upon the material of the measurement region and/or the amount of film growth on the measurement region, and the amount of light can be compared to known data to determine the adjusted growth rate reading. This data and/or equations may also take into account other optical properties, such as refractive index and/or extinction coefficient, to facilitate measurement accuracy.

The detector 576 can measure the growth rate of the second measurement region 286 shown in FIG. 2, the band edge detector 276 can measure the band edge wavelength of the first measurement region 285 shown in FIG. 2, and the upper temperature sensor 272 can measure the temperature of the third measurement region 287 shown in FIG. 2. The inner section 250 and outer section 131 can be rotationally stepped to align other measurement regions (or other sections thereof) and/or other substrates (or other sections thereof) under the ISR 585, the upper temperature sensor 272, and the band edge detector 276 for measurement purposes. The present disclosure contemplates that a plurality of measurements (for the same measurement region or across a variety of measurement regions) can be averaged for an adjusted value (e.g., a correction value) to be applied to measurements taken using the upper temperature sensor 272, the band edge detector 276, and/or the growth rate detector 576.

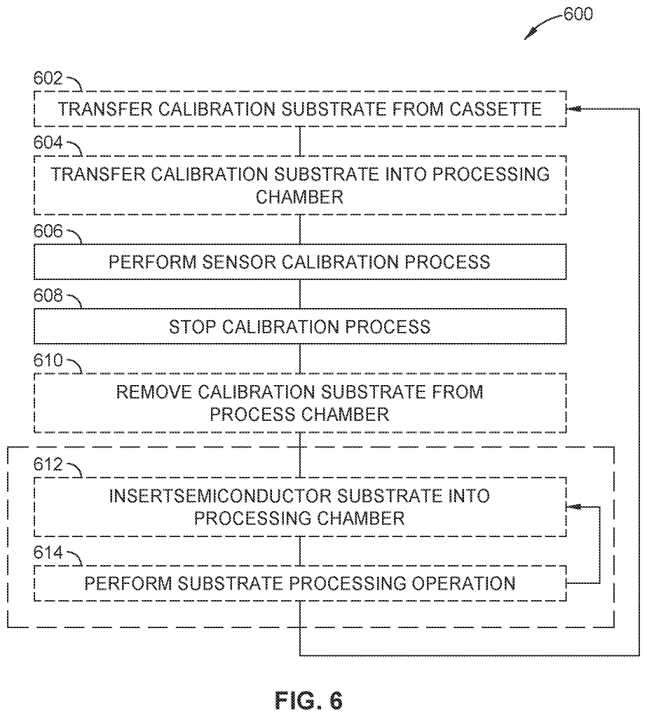

FIG. 6 is a schematic flow diagram view of a method 600 of using the processing system 100 of FIG. 1, according to one or more embodiments. The method 600 includes operations 602-614. In one or more embodiments, the operations 602, 604, 606, 608, 610, 612, and 614 are performed sequentially as shown in FIG. 6 and described herein. The present disclosure contemplates that other sequences may be used.

Optional operation 602 includes transferring one or more measurement regions, such as one or more of the measurement regions 285-287, 321, 322 from a cassette. In one or more embodiments, the one or more measurement regions are one or more measurement coupons. In one or more embodiments, the one or more measurement regions are one or more calibration coupons. The one or more measurement regions can be transferred on one or more inserts.

Optional operation 604 includes a transfer robot transferring the measurement region(s) into the processing chamber, such as the processing chamber 101. The measurement region(s) are supported, for example, by the inner section 250 carried by the transfer robot. The inner section 250 is placed onto the outer section 131 and the transfer robot is retracted from the process chamber 101.

The present disclosure contemplates that operations 602, 604 can be omitted, and the measurement region(s) and the inner section 250 can already be positioned in the processing chamber 101.

Operation 606 includes performing a measurement process. In one or more embodiments, the measurement process is a calibration process that calibrates one or more sensors. The measurement process includes using one or more (such as one, at least two, at least three, or all) of the measurement region(s) and the measurement assembly 270. The measurement process of the third operation 606 is described in greater detail with reference to the method 700 of determining measurements.

After operation 606, the measurement process is stopped in operation 608. Stopping the measurement process includes stopping the flow of any process gases introduced into the process chamber (if used), stopping of any heating of the measurement region(s), and ceasing of the measurement of parameter(s) of the measurement region(s).

After the measurement process is ceased, one or more of the measurement region(s) can be removed from the process chamber in operation 610. The measurement region(s) can be removed by the transfer robot through a loading port. The measurement region(s) are inserted back into the cassette subsequent to being removed from the process chamber 101. The present disclosure contemplates that operation 610 can be omitted, and the measurement region(s) and associated insert(s) can remain on the substrate support 130 during operations 612 and 614.

Optional operation 612 includes transferring a semiconductor substrate into the process chamber. The semiconductor substrate may be similar to the substrate 50 (FIG. 1). The semiconductor substrate may have partially formed semiconductor devices disposed thereon. The semiconductor substrate is transferred into the process chamber by the transfer robot and may have been stored within the cassette during the measurement process or may have been stored in a separate process chamber.

The present disclosure contemplates that optional operation 612 can include positioning the semiconductor substrate to cover one or more calibration substrates (such as the first measurement region 285 and the additional measurement region 321 shown in FIG. 2). Other measurement regions (such as the second measurement region 286, the third measurement region 287, and the additional measurement region 322 shown in FIG. 3) can remain uncovered by the semiconductor substrate.

Optional operation 614 includes performing a substrate processing operation. The substrate processing operation may include a deposition process on the top surface of the substrate. The substrate processing operation may further include heating the substrate, introducing at least one process gas, introducing a purge gas, and evacuating the process and purge gases. A plurality of substrates can be processed during the substrate processing operation. The present disclosure contemplates that one or more parameters of the substrate and/or the one or more measurement regions can be measured during operation 614. Operation 606 can be repeated during operation 614.

The optional operations 612, 614 can be repeated so that between each measurement process multiple substrates are processed. The optional operations 612, 614 may be repeated, such that more than 50 substrates are processed within the processing chamber between each measurement process. In one or more embodiments, the measurement process is performed once every several days and several hundred substrates are processed within the processing chamber between each measurement process. In one or more embodiments, the optional operations 612, 614 are omitted from the method 600.

The method 600 is repeated automatically after a preset amount of substrates have been processed within the processing chamber or after the processing chamber has reached a preset run time. The method 600 is automated and programmed into a controller, such as the controller 175. The method 800 may not use human intervention and can be completed without disassembly of the process chambers. The measurement using the method 600 can involve minimum downtime of the system by pausing processing operations for the length of time it takes to perform operations 606, 608 and re-initiating the processing operations after the length of time has elapsed, and/or by performing operation 606 during operation 614 involving processing.

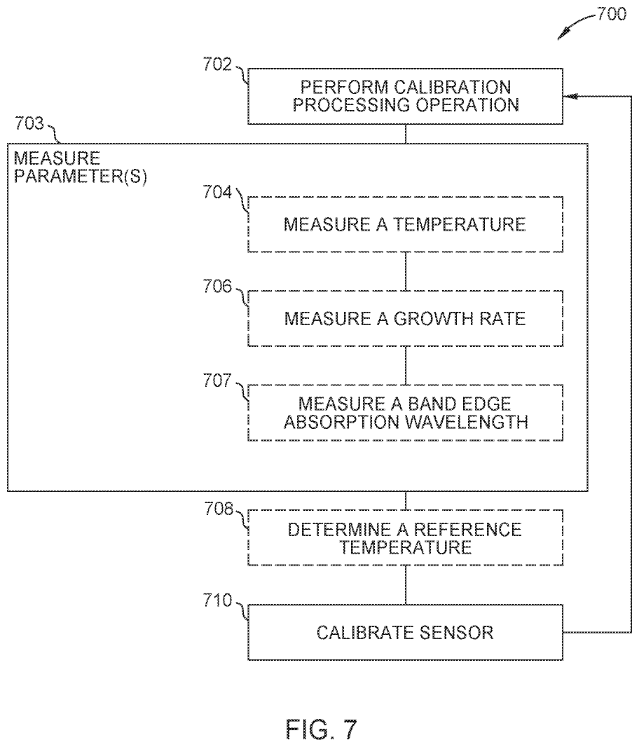

FIG. 7 is a schematic diagram view of a method 700 of determining measurements applicable for semiconductor manufacturing, according to one or more embodiments. The method 700 can be part of operation 606 of the method 600 described herein. Determining the measurements includes operations 702, 703, 704, 706, 707, 708, 710. The operations 702, 703, 704, 706, 707, 708, 710 described with regard to the method 700 can be performed subsequently as shown in FIG. 7 and described herein. Other sequences are contemplated. For example, operations 702, 703, 704, 706, 707, 708 can be performed simultaneously.

Operation 702 includes performing an initial processing operation. The initial processing operation can be, for example, a calibration processing operation. The initial processing operation may be similar to the substrate processing operation 614 performed on the substrate. The initial processing operation can include heating one or more (such as one, at least two, at least three, or each) of the measurement region(s), introducing a process gas, introducing a purge gas, and evacuating the process and purge gases. The process gas may be different from the process gas used in the substrate processing operation of operation 614 of the method 600. A process gas may include a reactive gas and a carrier gas, such as an H₂ gas. The carrier gas assists in matching process conditions with those found in the substrate processing operation 614 (which is optional to the method 600). The carrier gas assists in matching the pressure and gas flow which would be found during the substrate processing operation 614. In one or more embodiments, the process gas of operation 702 may not include reactive gases (e.g., deposition/etch gases), which may alter the surface(s) of the measurement region(s). The process chamber and measurement region(s) may be heated using the heat sources 164A, 164B and/or a substrate support heater. The heating of the process chamber and the measurement region(s) can be performed gradually and the temperature can increase over time.

Operation 703 includes measuring one or more parameters of one or more measurement regions (e.g., of one or more inserts).

Optional operation 704 of operation 704 includes measuring a temperature using the temperature sensor 272 and/or temperature sensor 278 (FIGS. 1, 2, 5). The temperature can be measured on one or more (such as one, at least two, at least three, or each) of the measurement region(s). The present disclosure contemplates that operation 702 can be omitted, and operation 704 can be conducted during operation 614 to measure the temperature on one or more substrates 50 (FIG. 1) being processed.

The temperature can be determined by measuring the radiation emitted by the measurement region or substrate. In one or more embodiments, the temperature sensors are pyrometers. The temperature measured by the upper temperature sensor 272 is a first temperature, or a first measured temperature. The temperature measured by the lower temperature sensor 278 is a second temperature, or a second measured temperature.

Optional operation 706 of operation 704 includes measuring a growth rate using the growth rate sensor 273 (FIGS. 1, 2, 5). The growth rate can be measured on one or more (such as one, at least two, at least three, or each) of the measurement region(s). The present disclosure contemplates that operation 702 can be omitted, and operation 706 can be conducted during operation 614 to measure the growth rate on one or more substrates 50 (FIG. 1) being processed.

Optional operation 707 of operation 704 includes measuring a wavelength of absorption (e.g., a band edge absorption wavelength) of one or more (such as one, at least two, at least three, or each) of the measurement region(s) using the band edge detector 276 (FIGS. 1, 2, 5). During operation 707 a first beam 486 is emitted by the energy source 274 or one of the heat sources 164A, 164B. When the first beam 486 strikes the top side of the measurement region(s) at a first location, a first wavelength range of the first beam 486 is absorbed by the measurement region while a second wavelength range of the first beam 486 is reflected as the second calibration beam 484. The second beam 484 enters the band edge detector 276. The band edge detector 276 measures the intensity of a variety of wavelengths within the wavelength spectrum of the second beam 484. The band edge detector 276 maps the intensity of the wavelength measurements over the wavelength range measured by the band edge detector 276. A broad band light source (such as the energy source 274) or one or more heat sources 164A, 164B are used to form the first beam 486. The energy source 274 may be beneficially used in order to improve the accuracy of the measurement. The energy source 274 may emit a precise range of wavelengths at a set intensity and direction. This makes the energy source 274 highly adjustable and may provide for improved measurement precision. The heat sources 164A, 164B may be used to reduce the number of components disposed on a lid of the process chamber. The heat sources 164A, 164B emit a range of light which may be similar to the range emitted by the energy source 274. The heat sources 164A, 164B have a controlled intensity. The heat sources 164A, 164B may be used to emit light which is absorbed and reflected by the measurement region(s). The heat sources 164A, 164B may be used with our without the energy source 274.

In one or more embodiments, radiation is transmitted through the measurement region(s) (such as the first measurement region 285 shown in FIG. 2) and measured by the band edge detector 276 on the opposite side of the measurement region(s) from the heat sources 164A, 164B. Such transmission can occur when the outer section 131 and/or the inner section 250 are transparent to the light emitted by the light source at a wavelength detected by the band edge detector 276 or when the inner section 250 and/or outer section 131 is opaque to the light and emits radiation after heating. Such transmission can also occur when the hole 279 (FIG. 2) is used below the first measurement region 285.

The band edge detector 276 may measure the intensity of wavelengths between about 250 nanometers (nm) to about 1350 nm, such as about 300 nm to about 1300 nm. The energy sources (the energy source 274 and/or the heat sources 164A, 164B) may emit light at a wavelength of about 250 nm to about 1350 nm, such as about 300 nm to about 1300 nm. Other wavelengths are contemplated.

The present disclosure contemplates that operation 702 can be omitted, and operation 707 can be conducted during operation 614 to measure the band edge absorption wavelength on one or more substrates 50 (FIG. 1) being processed.

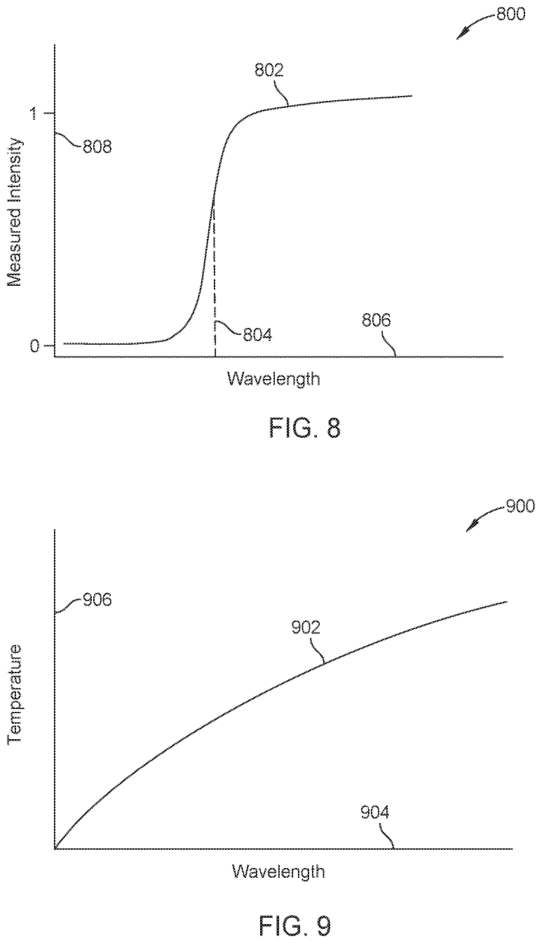

FIG. 8 shows the measurement of the intensity 808 of wavelengths over a range of wavelengths 806, according to one or more embodiments.

An exemplary map of the intensity of the wavelength measurements is in FIG. 8. The range of wavelengths 806 measured by the band edge detector 276 may be the same range of wavelengths emitted by the energy source 274 as the first beam 486. The intensity 808 of the wavelengths over the range of wavelengths 806 is mapped to form an intensity curve 802. The intensity curve 802 shows a sharp change between the wavelength range which is absorbed by the respective measurement region or substrate, the wavelength range having a low or near zero measured intensity, and the wavelength range which is reflected by the measurement region or substrate, the wavelength range having a high or near 1 measured intensity. The intensity is measured as a fraction of the intensity of the wavelength emitted by the energy source 274. The absorption edge wavelength is disposed in the midpoint 804 of the transition between low measured intensity and high measured intensity of the wavelength range. The absorption edge wavelength is the wavelength at which the wavelengths transition from being absorbed to being reflected by a material. The absorption edge wavelength is directly correlated to the band gap of a material and the band gap of a material is dependent upon the temperature of the material. As temperature changes within an object, such as the first measurement region 285 or substrate 50, the band gap and thus the absorption edge wavelength also changes. Therefore, a temperature of a material can be measured (e.g., a temperature reading adjusted) by measuring the absorption edge wavelength.

Returning to FIG. 7, in optional operation 708, the band edge detector 276 is used to determine a reference temperature of one or more (such as one, at least two, at least three, or each) of the measurement region(s) based off of the absorption edge wavelength(s) measure in operation 707. The present disclosure contemplates that operation 702 can be omitted, and optional operation 708 can be conducted during operation 614 to determine the reference temperature on one or more substrates 50 (FIG. 1) being processed. The reference temperature can be, for example, a calibration temperature.

FIG. 9 shows a correlated temperature graph 900, according to one or more embodiments. A graph such as the correlated temperature graph 900 shown in FIG. 9 is used to equate the absorption edge wavelength with a temperature (e.g., to determine the reference temperature of optional operation 708). The correlation curve 902 of the correlated temperature graph 900 may be found experimentally and correlates temperature 906 to the measured absorption edge wavelength 904. The temperature determined by the band edge detector 276 using the absorption edge wavelength is beneficial in that the determined temperature can account for inaccuracies due to the aging of any components of the process chamber, such as the process chamber 101. The absorption edge wavelength is dependent upon temperature and the material of the respective measurement region or substrate, and is relatively less influenced by the state of the components of the process chamber. Therefore, since the same measurement region(s) are used and stored between each of the measurement processes, an accurate and repeatable reference temperature is able to be performed using the measurement assembly 270 and the band edge detector 276. The reference temperature can be the temperature measured (e.g., adjusted) by the band edge detector 276. In one or more embodiments, the calibration reference is an actual temperature used for reference to adjust (e.g., calibrate) temperatures measured using the temperature sensor(s) (e.g., the first and second temperature sensors 272, 278 described herein).

Operation 710 of the method 700 includes comparing one or more of the one or more parameters (of operation 703). For example, one or more of the temperature (of operation 704), the growth rate (of operation 706), or the reference temperature (of operation 708) can be compared. The comparing can be used to calibrate one or more sensors (such as one or more of the sensors 272, 273, 276, 278). The present disclosure contemplates that operation 710 can be omitted.

Over time, the measurements of sensors can drift due to aging and wear of components of the process chamber. The measurements of the sensors 272, 273, 276, 278, can be taken (e.g., sensed) periodically. The sensors may be adjusted to a reading matching or near (e.g., within a predetermined degree of accuracy) a reference value. Using the reference value, a correction factor can be applied to subsequent measurements taken using the sensors (e.g., during epitaxial deposition processing).

In one or more embodiments, the method 700 of determining measurements described herein is performed multiple times at a variety of process parameters (such as processing temperatures) so that the sensors can sense measurements across a wide range of process parameters. The sensors can be calibrated for a wide range of process parameters. In one or more embodiments, an adjustment algorithm can determine an optimum calibration amount for the sensors after the method 700 has been repeated over a range of process parameters, over a range of semiconductor substrates, and/or over a range of a plurality of measurement regions (such as over the plurality of measurement regions 285-287, 321, 322). The sensors may be calibrated by adjusting each measurement by the same amount, or the sensors may be adjusted on a curve determined by the controller 175.

The present disclosure contemplates that operations 704, 706, 707, 708 can be conducted on a single measurement region and/or a single semiconductor substrate. The present disclosure contemplates that operations 704, 706, 707, 708 can be respectively conducted on a plurality of measurement regions and/or a plurality of semiconductor substrates. For example, the band edge absorption wavelength of operation 707 can be measured on the first measurement region 285, the growth rate of operation 706 can be measured on the second measurement region 286, and the temperature of operation 704 can be measured on the third measurement region 287.

The embodiments disclosed herein relate to using sensors to measure parameters of a thermal processing chamber, such as an epitaxial processing chamber. One or more measurement regions are used to facilitate accurate and more consistent measurement results.

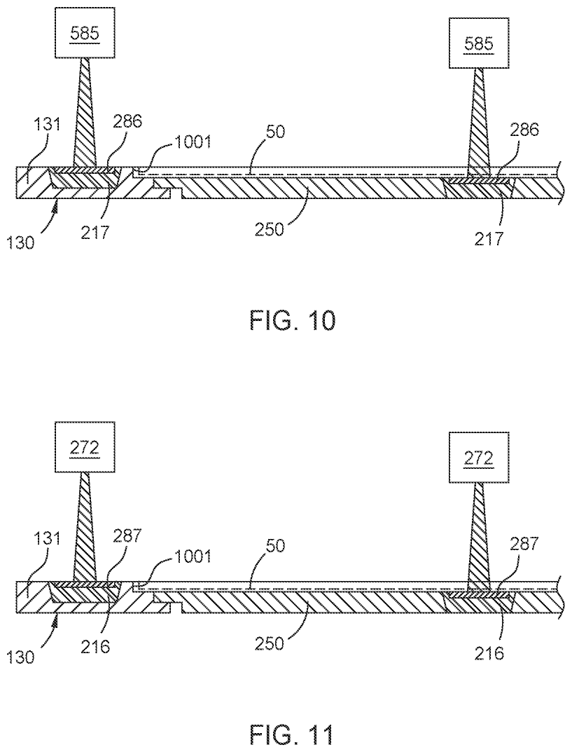

FIG. 10 is a schematic cross-sectional view a measurement assembly and the substrate support 130 shown in FIGS. 2 and 3, according to one or more embodiments.

The measurement assembly includes the ISR 585 operable to measure a growth rate on the second measurement region 286. An additional second measurement region 286 is disposed radially inwardly of the second measurement region 286, and an additional ISR 585 is disposed radially inwardly of the ISR 585. The outer section 131 of the substrate support 130 can include a shoulder 1001 defining a pocket that retains the substrate 50. The third insert 216, the second insert 217, the additional insert 312, and the plug inserts 303a-303e can be disposed radially outwardly of the shoulder 1001. The inserts 216, 217, 271, 312, 303a-303e are removably positioned respectively in the openings of the substrate support 130. The additional (inward) ISR 585 can be used to measure a growth rate on the additional second measurement region 286 when the additional second measurement region 286 is uncovered, and can be used to measure a growth rate on the substrate 50 when the additional second measurement region 286 is covered by the substrate 50. The outward ISR 585 can measure a growth rate on the second measurement region 286 both when the additional second measurement region 286 is covered by the substrate 50 and uncovered. The measurement assembly in FIG. 10 facilitates growth rate measurements during the presence and absence of the substrate 50, facilitates growth rate measurements for silicon film and silicon-germanium film, and facilitates growth rate measurements both for patterned substrates and blanket substrates. As an example, a growth rate measured on the outward second measurement region 286 can be used as a reference for growth on the substrate 50, such as when the substrate 50 is patterned. A ratio of growth rate measurements on the additional (inward) second measurement region 286 relative to growth rate measurements on the outward second measurement region 286 can be used for sensor measurement and/or measurement adjustment (e.g., calibration). A ratio of growth rate measurements on the uncovered additional (inward) second measurement region 286 relative to growth rate measurements on the substrate 50 after covering can be used for sensor measurement and/or measurement adjustment (e.g., calibration).

FIG. 11 is a schematic cross-sectional view a measurement assembly and the substrate support 130 shown in FIGS. 2 and 3, according to one or more embodiments.

The measurement assembly includes the temperature sensor 272 operable to measure a temperature on the third measurement region 287. An additional third measurement region 287 is disposed radially inwardly of the third measurement region 287, and an additional temperature sensor 272 is disposed radially inwardly of the temperature sensor 272. The additional (inward) temperature sensor 272 can be used to measure a temperature on the additional third measurement region 287 when the additional third measurement region 287 is uncovered, and can be used to measure a temperature on the substrate 50 when the additional third measurement region 287 is covered by the substrate 50. The outward temperature sensor 272 can measure a temperature on the third measurement region 287 both when the third measurement region 287 is covered by the substrate 50 and uncovered. The measurement assembly in FIG. 11 facilitates temperature measurements during the presence and absence of the substrate 50. A ratio of temperature measurements on the additional (inward) temperature relative to temperature measurements on the outward temperature can be used for sensor measurement and/or measurement adjustment (e.g., calibration). A ratio of temperature measurements on the uncovered additional (inward) temperature relative to temperature measurements on the substrate 50 after covering can be used for sensor measurement and/or measurement adjustment (e.g., calibration).

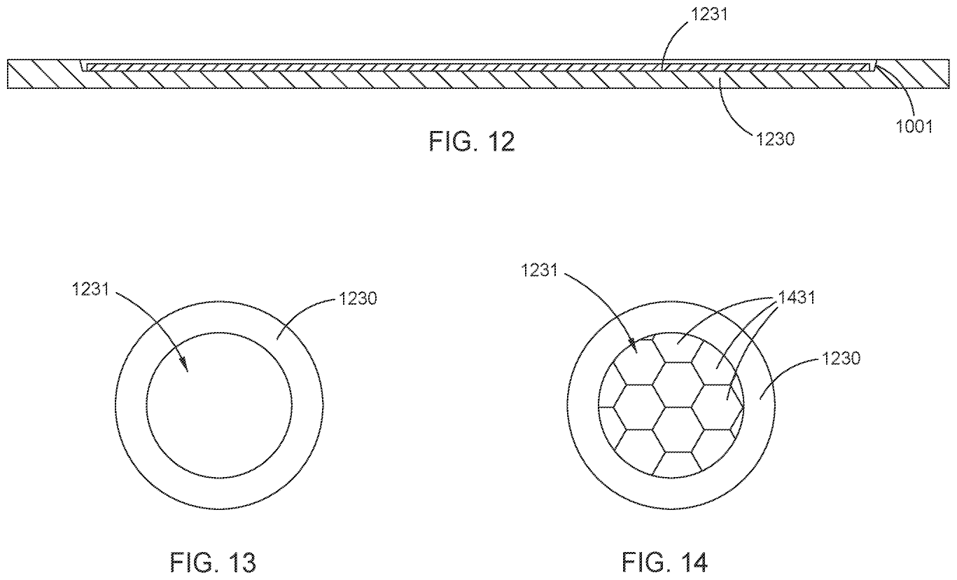

FIG. 12 is a schematic cross-sectional view of a substrate support 1230 and a measurement region 1231, according to one or more embodiments. The measurement region 1231 includes SiC that is polycrystalline or crystalline. The measurement region 1231 can have an outer diameter of about 300 mm. The temperature sensor 272, the band edge detector 276, and the growth rate sensor 273 can take measurements on various sections of the measurement region 1231 (such as on various portions of the disc in FIG. 13 or various measurement regions 1341 shown in FIG. 14).

FIG. 13 is a schematic top view of the substrate support 1230 and the measurement region 1231 shown in FIG. 12, according to one or more embodiments.

In the implementation shown in FIG. 13, the measurement region 1231 is a disc.

FIG. 14 is a schematic top view of the substrate support 1230 and the measurement region 1231 shown in FIG. 12, according to one or more embodiments.

In the implementation shown in FIG. 14, the measurement region 1231 separated (e.g., cut) into a plurality of measurement regions 1431 (e.g., a plurality of measurement coupons) abutting against each other. The plurality of measurement regions 1431 are hexagonal in shape, and can form a honeycomb pattern. The hexagonal measurement regions 1431 can have an outer diameter of about 4 inches.

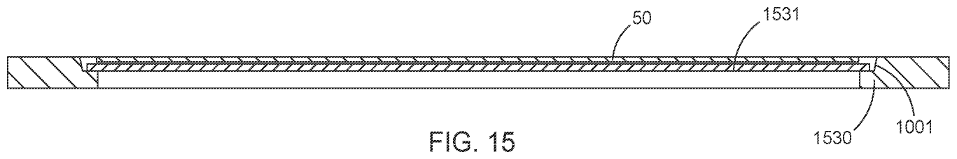

FIG. 15 is a schematic cross-sectional view of a substrate support 1530 and a measurement region 1531, according to one or more embodiments. The measurement region 1531 includes SiC that is polycrystalline or crystalline. The measurement region 1531 can have an outer diameter of about 300 mm. The measurement region 1531 is supported on a ledge of the substrate support 1530. The substrate support 1530 includes a curved body, such as a ring, surrounding an opening. The measurement region 1531 covers the opening of the curved body. The present disclosure contemplates that the measurement region 1531 can include polycrystalline SiC, and the hexagonal measurement regions 1431 shown in FIG. 14 can be stacked on the measurement region 1531. In such an embodiment, the hexagonal measurement regions 1431 can include crystalline SiC.

The implementations shown in FIGS. 12-15 can facilitate site flatness for processed substrates. The implementation shown in FIG. 15 can facilitate a lower mass substrate support, which can facilitate ease of movement, ease of manufacturing, and heating efficiency (such as semi-transparent heating from bottom including transmission at relative lower wavelength IR heating from bottom heat sources 164B).

Benefits of the present disclosure include accurate measurements; accurate adjustment and calibration of measurements (such as temperature measurements); continuous measuring and monitoring; increased measurement sites; measurements that account for aging and wear of chamber components; measurements (such as growth rates) with and/or without presence of processed substrates; and longer operational lifespans for measurement regions. For example, using the subject matter described herein accurate measurements can be taken and/or adjusted for silicon growth and silicon germanium growth, and for substrates having relatively smooth surfaces and relatively rough surfaces. Benefits also include enhanced surface flatness, heating efficiency (such as energy transmission), thermal conductivity, and enhanced support for substrates on substrate supports.

It is contemplated that one or more aspects disclosed herein may be combined. As an example, one or more aspects, features, components, operations and/or properties of the processing system 100, the process chamber 101, the controller 175, the growth rate sensor 273, the temperature sensors 272, 278, the band edge detector 276, the inner section 250, the outer section 131, one or more (such as one, at least two, at least three or all) of the measurement regions 285-287, 321, 322, the ISR 585, the method 600, the method 700, the profile(s) of FIG. 8, the profile(s) of FIG. 9, the implementation shown in FIG. 10, the implementation shown in FIG. 11, the measurement region 1231, the substrate support 1230, the measurement regions 1431, the substrate support 1530, and/or the measurement region 1531 may be combined. Moreover, it is contemplated that one or more aspects disclosed herein may include some or all of the aforementioned benefits.

While the foregoing is directed to examples of the present disclosure, other and further examples of the disclosure may be devised without departing from the basic scope thereof, and the scope thereof is determined by the claims that follow.

What is claimed is:

1. A substrate support assembly applicable for semiconductor manufacturing, comprising:
a substrate support comprising a plurality of openings; and
a first insert sized and shaped for positioning in a first opening of the substrate support, the first insert comprising a first measurement region.

2. The substrate support of claim 1, wherein the first measurement region and the second measurement region respectively include a crystalline silicon carbide (SiC).

3. The substrate support of claim 1, further comprising:
a second insert sized and shaped for positioning in a second opening of the substrate support, the second insert comprising a second measurement region.

4. The substrate support of claim 3, wherein the substrate support includes silicon carbide (SiC) having an atomic structure that is 3C.

5. The substrate support of claim 3, further comprising:
a third insert sized and shaped for positioning in a third opening of the substrate support, the third insert comprising a third measurement region, wherein the first measurement region and the third measurement region respectively include SiC having an atomic structure that is 4H or 6H, wherein the second opening is disposed radially outwardly of the first opening, and the third opening is disposed radially between the first opening and the second opening.

6. The substrate support of claim 1, wherein the first insert comprises one or more outer surfaces sized and shaped to abut against one or more inner surfaces defined at least partially by the first opening of the substrate support.

7. The substrate support of claim 6, wherein the one or more outer surfaces have a taper angle that is substantially equal to a taper angle of the one or more inner surfaces.

8. The substrate support of claim 3, wherein: the first measurement region includes a first measurement coupon sized and shaped for positioning in a first retention opening of the first insert, the first retention opening comprising a first recess at least partially defining a first support surface, and a hole extending into the first support surface; and
the second measurement region includes a second measurement coupon sized and shaped for positioning in a second retention opening of the second insert, the second retention opening comprising a second recess at least partially defining a second support surface.

9. The substrate support of claim 8, further comprising a third insert sized and shaped for positioning in a third opening of the substrate support, the third insert comprising a third measurement region, and the third retention opening comprising a third recess at least partially defining a third support surface.

10. The substrate support assembly of claim 1, wherein the substrate support comprises:
an inner section including the first opening; and
an outer section sized and shaped to support an outer region of the inner section, the outer section including the second opening.

11. A processing chamber, comprising:
a chamber body at least partially defining a processing volume;
a substrate support disposed in the processing volume;
one or more measurement regions at least partially supported by the substrate support, the one or more measurement regions respectively including a crystalline silicon carbide (SiC); and
one or more heat sources operable to heat the processing volume.

12. The processing chamber of claim 11, wherein the one or more measurement regions comprise one or more inserts removably positioned respectively in one or more openings of the substrate support.

13. The processing chamber of claim 11, further comprising a sensor assembly comprising:
an energy source positioned to emit a first energy toward a first section of the one or more measurement regions; and
a band edge detector positioned to receive the first energy.

14. The processing chamber of claim 13, further comprising:
a temperature sensor positioned to emit a second energy toward a second section of the one or more measurement regions and receive the second energy.

15. The processing chamber of claim 13, wherein the sensor assembly further comprises:
a collimator in optical communication with a second energy source along a propagation path;
a dichroic mirror disposed along the propagation path between the collimator and a passage, wherein a growth rate sensor is in optical communication with the dichroic mirror along a propagation sub-path downstream of the dichroic mirror; and
a filter disposed along the propagation path between the second energy source and the growth rate sensor.

16. The processing chamber of claim 13, wherein the one or more measurement regions comprise a plurality of measurement coupons abutting against each other, and the plurality of measurement coupons are hexagonal in shape.

17. A method of operation of a process chamber, the method comprising:
measuring one or more parameters of one or more inserts positioned at least partially in a substrate support.

18. The method of claim 17, further comprising comparing the one or more parameters, wherein the one or more parameters comprise a temperature, a growth rate, and a band edge absorption wavelength measured on a single measurement region of the one or more inserts.

19. The method of claim 17, wherein the one or more parameters comprise:
a band edge absorption wavelength measured on a first measurement region of the one or more inserts;
a growth rate measured on a second measurement region of the one or more inserts; and
a temperature measured on a third measurement region of the one or more inserts.

20. The method of claim 19, further comprising:
positioning a substrate to cover one or more of the first measurement region or the second measurement region;
performing a processing operation on the substrate, the processing operation comprising:
heating the substrate, and
flowing a process gas over the substrate.
